(19) United States
(12) Patent Application Publication
(10) Pub. No.: US 2025/0176140 A1
(43) Pub. Date: May 29, 2025

(54) HOLLOW PIPE COOLING DEVICE

(71) Applicant: Delta Electronics, Inc., Taoyuan City (TW)

(72) Inventors: Jung-Sung Shih, Taoyuan City (TW); Yu-Hsien Nien, Taoyuan City (TW); Yu-Hung Huang, Taoyuan City (TW)

(21) Appl. No.: 18/945,313

(22) Filed: Nov. 12, 2024

Related U.S. Application Data
(60) Provisional application No. 63/602,739, filed on Nov. 27, 2023.

(30) Foreign Application Priority Data
Aug. 23, 2024 (CN) 202422059859.1

(51) Int. Cl. H05K 7/20

(52) U.S. Cl. CPC H05K 7/20336

(57) ABSTRACT

A hollow pipe cooling device includes a covering member, a spacer member and a hollow pipe. A top surface of the spacer member is partially exposed to a top cover opening of the covering member. The hollow pipe includes a surrounding wall part and a closed end part. A first end of the surrounding wall part is connected with the closed end part. A second end of the surrounding wall part is an opened end part. A heat dissipation space is defined by the surrounding wall part and the closed end part collaboratively. The opened end part is used as an entrance/exit of the heat dissipation space. A hollow pipe wick structure is formed on an inner wall of the surrounding wall part. The opened end part is aligned with the corresponding top cover opening and contacted with the spacer member.

### CROSS-REFERENCE TO RELATED APPLICATION

This application claims the benefit of U.S. Provisional Application Ser. No. 63/602,739 filed on Nov. 27, 2023, and claims priority to China Patent Application No. 202422059859.1 filed on Aug. 23, 2024, the entire contents of which are incorporated herein by reference for all purposes.

### FIELD OF THE INVENTION

The present invention relates to a cooling device, and more particularly to a hollow pipe cooling device with a special structure design to improve the cooling efficiency and strengthen the overall structure.

### BACKGROUND OF THE INVENTION

With the advancement of science and technology, the computing power of computer systems has been greatly improved. The uses of high-performance electronic components lead to a rapid increase of the heat generation. If the computer system is operated in a high-temperature environment for a long time, the life of the electronic components will be shortened, and the operation of the computer system will be unstable.

For removing the heat energy, various heat dissipation devices have been developed. For example, a heat dissipation device includes a combination of a plurality of heat pipes and a vapor chamber. After the heat pipes are inserted into a bottom plate of the vapor chamber, the heat pipes and the vapor chamber are combined together. Consequently, the open ends of the heat pipes are in direct contact with the wick structures of the bottom plate of the vapor chamber.

However, the above heat dissipation device still has some drawbacks. For example, during the assembling process, the space within the housing of the vapor chamber cannot be visually inspected. That is, the connection between the heat pipes and the wick structures in the bottom plate of the vapor chamber cannot be ensured. This design will result in the maximum heat transfer, the high thermal resistance value or the unstable characteristics.

As mentioned above, the opened ends of the heat pipes are directly inserted into the bottom plate of the vapor chamber. Conventionally, lateral openings are formed near the open ends of the heat pipes as the steam communication channels. Through the lateral openings, gas and liquid can be effectively circulated in the hollow pipe cooling system. The size of the lateral opening will affect the overall quality. If the lateral opening is too small, the steam path will be adversely affected. If the lateral opening is too large, the joint strength between the heat pipe and the vapor chamber will be influenced, and the connection between the heat pipes and the wick structures in the bottom plate of the vapor chamber will result in the poor water recycle efficiency.

Therefore, there is a need of providing a hollow pipe cooling device with a wick support structure to be contacted and aligned with the hollow pipe, and thus the cooling efficiency is improved, and the overall structure is strengthened.

### SUMMARY OF THE INVENTION

The present invention provides a hollow pipe cooling device with a covering member, a hollow pipe and a spacer member. A top cover opening of the covering member is aligned with the opened end part of the hollow pipe. The spacer member and the opened end part of the hollow pipe are contacted with each other. Consequently, the cooling performance is enhanced, and the overall structural strength is increased.

The present invention provides a hollow pipe cooling device with a covering member, a hollow pipe and a spacer member. The hollow pipe and the top cover opening are assembled with each other in a first direction. The process of contacting the opened end part of the hollow pipe with the spacer member is visualized. Consequently, the integrity of the contact between the opened end part of the hollow pipe and the spacer member is ensured, and the product yield is increased.

In accordance with an aspect of the present invention, a hollow pipe cooling device is provided. The hollow pipe cooling device includes a covering member, a spacer member and at least one hollow pipe. The covering member includes a top cover and a bottom cover. The top cover and the bottom cover are combined together, and thus an accommodation space is formed between the top cover and the bottom cover. The top cover includes at least one top cover opening. The least one top cover opening runs through the top cover in a first direction and is in communication with the accommodation space. The spacer member is disposed in the accommodation space. The spacer member has a top surface. The top surface is partially exposed to the at least one top cover opening. Each of the at least one hollow pipe includes a surrounding wall part and a closed end part. A first end of the surrounding wall part is connected with the closed end part. A second end of the surrounding wall part is an opened end part. A heat dissipation space is defined by the surrounding wall part and the closed end part collaboratively. The opened end part is used as entrance/exit of the heat dissipation space. A hollow pipe wick structure is formed on an inner wall of the surrounding wall part. The opened end part is aligned with the corresponding top cover opening and contacted with the spacer member.

In an embodiment, the hollow pipe cooling device further includes a top wick structure, and the top wick structure is disposed on a surface of the top cover facing the accommodation space.

In an embodiment, the spacer member is contacted with the top wick structure.

In an embodiment, the top wick structure is a grooved structure, a copper powder sintered structure, a woven mesh structure or a composite structure.

In an embodiment, the hollow pipe cooling device further includes a bottom wick structure disposed on a surface of the bottom cover facing the accommodation space.

In an embodiment, the spacer member is contacted with the bottom wick structure.

In an embodiment, the bottom wick structure is a grooved structure, a copper powder sintered structure, a woven mesh structure or a composite structure.

In an embodiment, the bottom cover includes a first area, a second area and a third area, wherein the second area is arranged around the first area, the second area and the first area are located at different horizontal planes, the third area is connected with the second area and the first area, and the third area is arranged between the second area and the first area.

In an embodiment, the spacer member is a convex structure, a battlement structure, a sawtooth structure or a columnar structure.

In an embodiment, the spacer member is a copper powder sintered structure, a woven mesh structure or a composite structure.

In an embodiment, the spacer member includes a plurality of support structures, and the plurality of support structures are in a parallel arrangement, a mesh arrangement or a radial arrangement.

In an embodiment, the hollow pipe wick structure is a grooved structure, a copper powder sintered structure, a woven mesh structure or a composite structure.

In accordance with another aspect of the present invention, a hollow pipe cooling device is provided. The hollow pipe cooling device includes a covering member, a spacer member and at least one hollow pipe. The covering member includes a top cover and a bottom cover. The top cover and the bottom cover are combined together, and thus an accommodation space is formed between the top cover and the bottom cover. The top cover includes at least one top cover opening. The least one top cover opening runs through the top cover in a first direction and is in communication with the accommodation space. The spacer member is disposed in the accommodation space. The spacer member includes a top surface and at least one bulge. The top surface is partially exposed to the at least one top cover opening. The at least one bulge is extended in the first direction. Each of the at least one hollow pipe includes a surrounding wall part and a closed end part. A first end of the surrounding wall part is connected with the closed end part. A second end of the surrounding wall part is an opened end part. A heat dissipation space is defined by the surrounding wall part and the closed end part collaboratively. The opened end part is used as entrance/exit of the heat dissipation space. A hollow pipe wick structure is formed on an inner wall of the surrounding wall part. The opened end part is combined with the corresponding top cover opening.

In accordance with another aspect of the present invention, a hollow pipe cooling device is provided. The hollow pipe cooling device includes a covering member, a spacer member and at least one hollow pipe. The covering member includes a top cover and a bottom cover. The top cover and the bottom cover are combined together, and thus an accommodation space is formed between the top cover and the bottom cover. The top cover includes at least one top cover opening and at least one extended portion. The least one top cover opening runs through the top cover in a first direction and is in communication with the accommodation space. The at least one extended portion is externally extended from the corresponding top cover opening. The spacer member is disposed in the accommodation space. The spacer member has a top surface. The top surface is partially exposed to the at least one top cover opening. Each of the at least one hollow pipe includes a surrounding wall part and a closed end part. A first end of the surrounding wall part is connected with the closed end part. A second end of the surrounding wall part is an opened end part. A heat dissipation space is defined by the surrounding wall part and the closed end part collaboratively. The opened end part is used as entrance/exit of the heat dissipation space. A hollow pipe wick structure is formed on an inner wall of the surrounding wall part. The opened end part is aligned with the corresponding top cover opening and contacted with the spacer member. The opened end part is enclosed by the corresponding extended portion of the top cover.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a hollow pipe cooling device according to a first embodiment of the present invention;

FIG. 2 is a schematic exploded view illustrating the hollow pipe cooling device according to the first embodiment of the present invention;

FIG. 3 is a schematic perspective view illustrating a spacer member of the hollow pipe cooling device according to the first embodiment of the present invention;

FIG. 4 is a schematic perspective view illustrating a bottom cover of the hollow pipe cooling device according to the first embodiment of the present invention;

FIG. 5 is a schematic cross-sectional view illustrating the hollow pipe cooling device according to the first embodiment of the present invention;

FIG. 6 is a schematic cross-sectional view illustrating an enlarged portion of the hollow pipe cooling device shown in FIG. 5;

FIG. 7 is a schematic cross-sectional view illustrating a hollow pipe cooling device according to a second embodiment of the present invention;

FIG. 8 is a schematic cross-sectional view illustrating an enlarged portion of the hollow pipe cooling device according to the second embodiment of the present invention;

FIG. 9A is a schematic perspective view illustrating a first support structure of the hollow pipe cooling device according to the second embodiment of the present invention;

FIG. 9B is a schematic perspective view illustrating a first support structure of a hollow pipe cooling device according to a third embodiment of the present invention;

FIG. 9C is a schematic perspective view illustrating a first support structure of a hollow pipe cooling device according to a fourth embodiment of the present invention;

FIG. 9D is a schematic perspective view illustrating a first support structure of a hollow pipe cooling device according to a fifth embodiment of the present invention;

FIG. 10 is a schematic cross-sectional view illustrating a hollow pipe cooling device according to a sixth embodiment of the present invention;

FIG. 11 is a schematic cross-sectional view illustrating an enlarged portion of the hollow pipe cooling device according to the sixth embodiment of the present invention;

FIG. 12A is a schematic cross-sectional view illustrating a second support structure of a hollow pipe cooling device according to a seventh embodiment of the present invention;

FIG. 12B is a schematic cross-sectional view illustrating a second support structure of a hollow pipe cooling device according to an eighth embodiment of the present invention;

FIG. 12C is a schematic cross-sectional view illustrating a second support structure of a hollow pipe cooling device according to a ninth embodiment of the present invention;

FIG. 13A is a schematic perspective view illustrating a bottom cover of the hollow pipe cooling device according to a tenth embodiment of the present invention;

FIG. 13B is a schematic perspective view illustrating a bottom cover of the hollow pipe cooling device according to an eleventh embodiment of the present invention; and

FIG. 13C is a schematic perspective view illustrating a bottom cover of the hollow pipe cooling device according to a twelfth embodiment of the present invention.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “about” decorator. Accordingly, unless otherwise indicated, the numerical parameters of the present invention and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

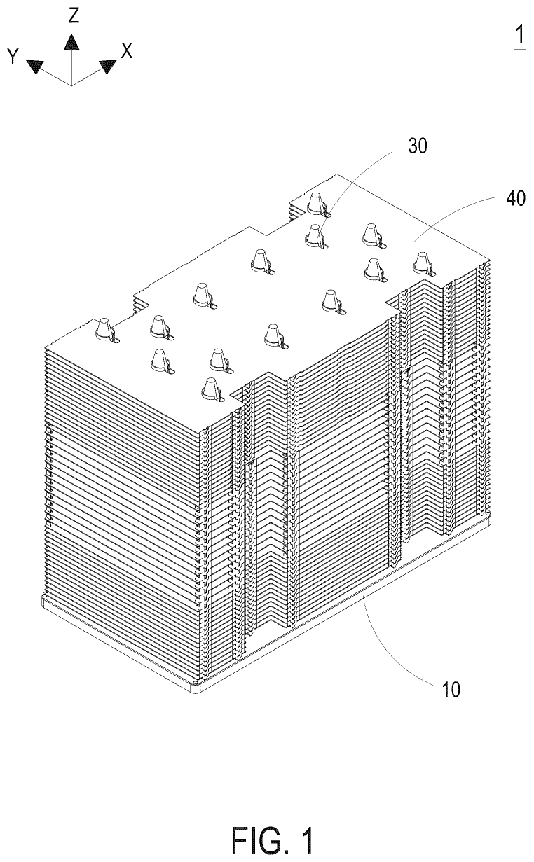

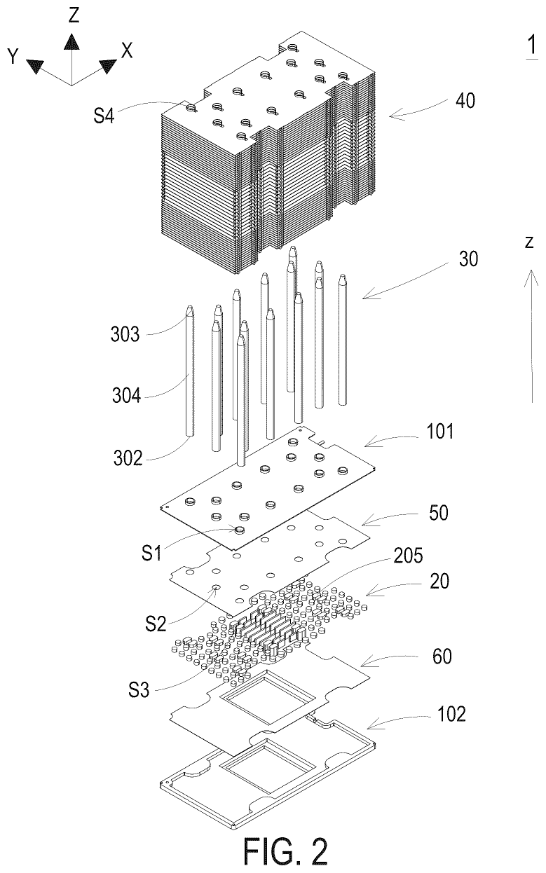

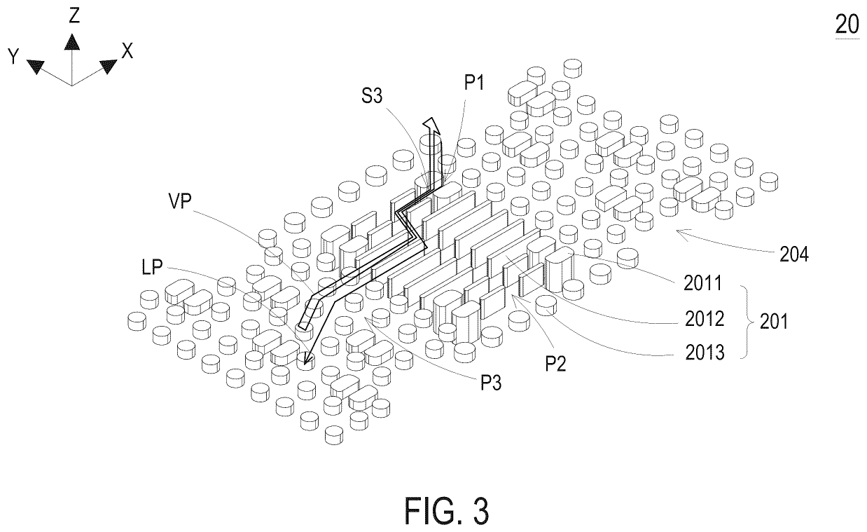

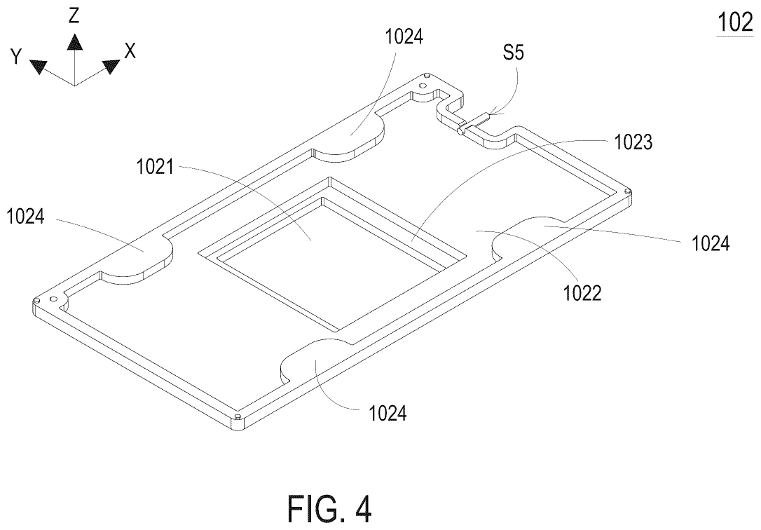

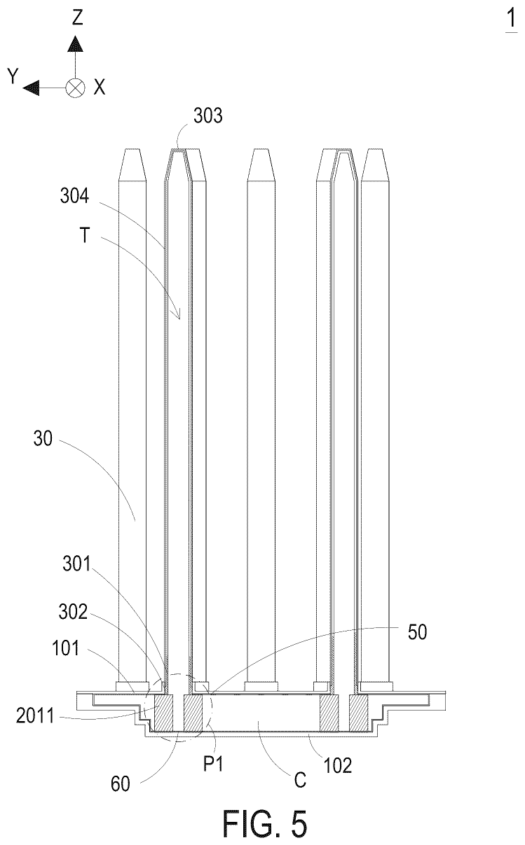

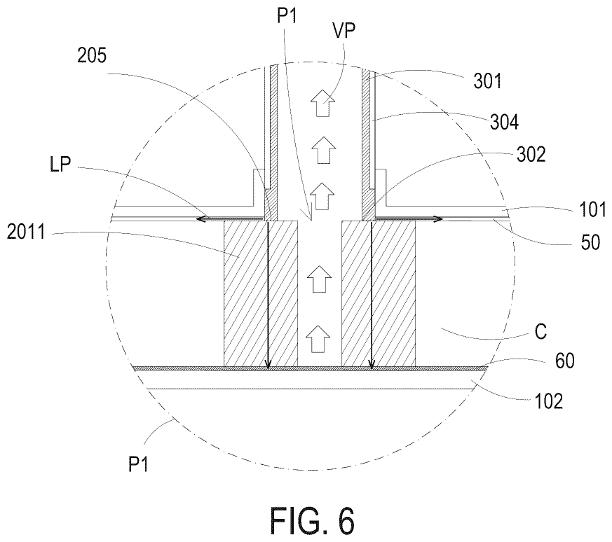

FIG. 1 is a schematic perspective view illustrating a hollow pipe cooling device according to a first embodiment of the present invention. FIG. 2 is a schematic exploded view illustrating the hollow pipe cooling device according to the first embodiment of the present invention. FIG. 3 is a schematic perspective view illustrating a spacer member of the hollow pipe cooling device according to the first embodiment of the present invention. FIG. 4 is a schematic perspective view illustrating a bottom cover of the hollow pipe cooling device according to the first embodiment of the present invention. FIG. 5 is a schematic cross-sectional view illustrating the hollow pipe cooling device according to the first embodiment of the present invention. FIG. 6 is a schematic cross-sectional view illustrating an enlarged portion of the hollow pipe cooling device shown in FIG. 5. The hollow pipe cooling device 1 includes a covering member 10, a spacer member 20 and at least one hollow pipe 30.

The covering member 10 includes a top cover 101 and a bottom cover 102. The top cover 101 and the bottom cover 102 are assembled with each other in a first direction z. In addition, an accommodation space C is formed between the top cover 101 and the bottom cover 102. The top cover 101 includes at least one top cover opening S1. The least one top cover opening S1 runs through the top cover 101. In addition, the at least one top cover opening S1 is in communication with the accommodation space C. Preferably but not exclusively, the covering member 10 is a vaper chamber.

The spacer member 20 is disposed in the accommodation space C. The spacer member 20 has a top surface 205. The top surface 205 faces the at least one hollow pipe 30. In addition, the top surface 205 is partially exposed to the at least one top cover opening S1.

Each hollow pipe 30 includes a surrounding wall part 304 and a closed end part 303. A first end of the surrounding wall part 304 is connected with the closed end part 303. A second end of the surrounding wall part 304 is an opened end part 302. The surrounding wall part 304 and the closed end part 303 are collaboratively formed as a heat dissipation space T. The opened end part 302 is used as the entrance/exit of the heat dissipation space T. A hollow pipe wick structure 301 is formed on an inner wall of the surrounding wall part 304. Preferably but not exclusively, the hollow pipe 30 is a heat pipe. The opened end part 302 is aligned with the corresponding top cover opening S1 and contacted with the top surface 205 of the spacer member 20. The exposed portion of the spacer member 20 is contacted with the opened end part 302 of the hollow pipe 30. Consequently, the structural strength of the hollow pipe cooling device 1 can be ensured. Since the hollow pipe 30 is assembled with the corresponding top cover opening S1 in the first direction z, the process of contacting the opened end part 302 of the hollow pipe 30 with the spacer member 20 is visualized. Under this circumstance, the integrity of the contact between the opened end part 302 of the hollow pipe 30 and the spacer member 20 is ensured, and the product yield is increased.

In an embodiment, the spacer member 20 includes at least one columnar structure. Preferably but not exclusively, the spacer member 20 is a copper powder sintered structure, a woven mesh structure or a composite structure. In this embodiment, the spacer member 20 includes a plurality of support structures 201. For example, the plurality of support structures 201 include at least one first support structure 2011, at least one second support structure 2012 and at least one third support structure 2013. A portion of the first support structure 2011 is aligned with and exposed to the top cover opening S1 in the first direction z. After the assembling process is completed, the opened end part 302 of the hollow pipe 30 is contacted with the corresponding first support structure 2011. Furthermore, the support structures 2011, 2012 and 2013 are in parallel with each other. It is noted that the shape of the spacer member 20 is not restricted. For example, in some other embodiments, the support structure of the spacer member 20 is a convex structure, a battlement structure or a sawtooth structure. In an embodiment, the plurality of support structures 201 are in a mesh arrangement or a radial arrangement and collaboratively formed as the spacer member 20.

Preferably but not exclusively, the hollow pipe wick structure 301 is a grooved structure, a copper powder sintered structure, a woven mesh structure or a composite structure.

In an embodiment, the bottom cover 102 includes a first area 1021, a second area 1022 and a third area 1023. The second area 1022 is arranged around the first area 1021. The second area 1022 and the first area 1021 are located at different horizontal planes. The third area 1023 is connected with the second area 1022 and the first area 1021. In addition, the third area 1023 is arranged between the second area 1022 and the first area 1021. The first area 1021, the second area 1022 and the third area 1023 of the bottom cover 102 are related to each other to comply with the diversified design of the heat source appearance. The altitude of the first area 1021 is lower than the altitude of the second area 1022 and the altitude of the third area 1023 in the first direction z. The first area 1021 of the bottom cover 102 is in contact with a heat source (not shown). After the condensed liquid is collected in the first area 1021 of the bottom cover 102 through the second area 1022 and the third area 1023 of the bottom cover 102, the condensed liquid collected in the first area 1021 of the bottom cover 102 is sublimated into steam by the heat source. Consequently, the circulating and cooling function can be achieved.

In an embodiment, the hollow pipe cooling device 1 further includes a top wick structure 50. The top wick structure 50 is formed on a surface of the top cover 101 facing the accommodation space C. The spacer member 20 is contacted with the top wick structure 50. The top wick structure 50 is a grooved structure, a copper powder sintered structure, a woven mesh structure or a composite structure. The top wick structure 50 is disposed on the top surface of the spacer member 20. The top surface of the top wick structure 50 is contacted with the top cover 101 and the first support structure 2011. The top wick structure 50 further includes at least one top wick structure opening S2. The at least one top wick structure opening S2 is aligned with the corresponding top cover opening S1. The top surface of the first support structure 2011 is contacted with the opened end part 302 of the hollow pipe 30. In addition, the top wick structure 50 is contacted with the hollow pipe wick structure 301 of the hollow pipe 30. Since the top wick structure 50 is in direct contact with the hollow pipe wick structure 301, the condensed liquid can be transferred to the accommodation space C through the capillary action. In other words, the effective circulating purpose can be achieved.

In an embodiment, the hollow pipe cooling device 1 further includes a bottom wick structure 60. The bottom wick structure 60 is formed on a surface of the bottom cover 102 facing the accommodation space C. The spacer member 20 is contacted with the bottom wick structure 60. The bottom wick structure 60 is a grooved structure, a copper powder sintered structure, a woven mesh structure or a composite structure. The bottom wick structure 60 is disposed on the bottom surface of the spacer member 20. The bottom wick structure 60 is contacted with the bottom cover 102 and the bottom surface of the at least one first support structure 2011. In addition, a portion of the bottom wick structure 60 is connected with the top wick structure 50. The condensed liquid is transferred to the top wick structure 50 through the capillary action. Since the top wick structure 50 is contacted with the bottom wick structure 60, the condensed liquid is continuously transferred to the bottom wick structure 60 through the capillary action. As mentioned above, the bottom cover 102 is divided into three areas, and the altitudes of the three areas are different in the first direction z. That is, the bottom cover 102 is has a stepped structure. After the condensed liquid is collected in the first area 1021 of the bottom cover 102 corresponding to the heat source, the condensed liquid collected in the first area 1021 of the bottom cover 102 is sublimated into steam by the heat source and transferred to the hollow pipe 30. Consequently, the circulating and cooling function can be achieved.

In an embodiment, the first support structure 2011 includes at least one first support structure opening S3. The first support structure opening S3 is aligned with the corresponding hollow pipe 30. In addition, the first support structure opening S3 is in communication with the heat dissipation space T of the hollow pipe 30, and thus a first flow channel P1 is defined. In other words, the first flow channel P1 is defined by the heat dissipation space T of the hollow pipe 30 and the first support structure opening S3 collaboratively. In the first flow channel P1, the steam is transferred in the direction toward the closed end part 303 along a steam path VP, and the steam is condensed into the liquid in the hollow pipe wick structure 301. Then, the liquid is transferred in the direction toward the accommodation space C along a liquid path LP. Since the top wick structure 50 and the first support structure 2011 are connected with each other and both of the top wick structure 50 and the first support structure 2011 are grooved structures, copper powder sintered structures, woven mesh structures or composite structures, the liquid is transferred in the liquid path LP along multiple directions. As shown in FIG. 6, the liquid is transferred in the liquid path LP along the first direction z and the direction perpendicular to the first direction. Due to this structural design, the liquid reflux speed is increased, and the cooling efficacy is enhanced.

In an embodiment, a plurality of second support structures 2012 of the spacer member 20 are disposed on the first area 1021 of the bottom cover 102. The plurality of second support structures 2012 are located beside the first support structures 2011. The top surface of the second support structure 2012 is contacted with the top cover 101 and the top wick structure 50. The bottom surface of the second support structure 2012 is contacted with the bottom cover 102 and the bottom wick structure 60. Due to this structural design, the external pressures on the top cover 101 and the bottom cover 102 can be effectively supported. In addition, a second flow channel P2 is defined by the plurality of second support structures 2012. The second flow channel P2 is in communication with the first flow channel P1. Consequently, the efficiency of circulating the steam and the condensed liquid can be effectively enhanced.

In an embodiment, a plurality of third support structures 2013 of the spacer member 20 are disposed on the second area 1022 of the bottom cover 102. The top surface of the third support structure 2013 is contacted with the top cover 101 and the top wick structure 50. The bottom surface of the third support structure 2013 is contacted with the bottom cover 102 and the bottom wick structure 60. In addition, a third flow channel P3 is defined by the plurality of third support structures 2013. The third flow channel P3 is in communication with the first flow channel P1 and the second flow channel P2.

As mentioned above, the top surfaces and the bottom surfaces of the support structures 201 are respectively contacted with the top wick structure 50 and the bottom wick structure 60. In addition, the third flow channel P3 is included in the second area 1022 of the bottom cover 102. The third flow channel P3 encloses the first support structures 2011. Due to this structural design, the external pressures on the top cover 101 and the bottom cover 102 can be effectively supported. Moreover, since the third flow channel P3 is in communication with the first flow channel P1 and the second flow channel P2, the efficiency of circulating the steam and the condensed liquid can be effectively enhanced.

In an embodiment, the bottom cover 102 includes a bottom cover opening S5. The bottom cover opening S5 is in communication with the third flow channel P3. After the hollow pipe cooling device 1 is assembled, a cooling liquid can be injected into the hollow pipe cooling device 1 through the bottom cover opening S5. Since the bottom cover opening S5 is in communication with the third flow channel P3, the cooling liquid flows to the third flow channel P3 through the bottom cover opening S5. Moreover, since the third flow channel P3 is in communication with the first flow channel P1 and the second flow channel P2, the cooling liquid can be guided to the nearby region of the target heat source.

In an embodiment, the hollow pipe cooling device 1 includes a plurality of fins 40 and a plurality of fin openings S4. The plurality of fin openings S4 are aligned with the respective hollow pipes 30, and thus the plurality of fins 40 are contacted with the hollow pipes 30. Since the heat transfer surface area contacting with the ambient medium is expanded, the cooling efficacy can be further increased.

In an embodiment, the bottom cover 102 includes a protrusion structure 1024, and the spacer member 20 includes a concave structure 204. The protrusion structure 1024 and a concave structure 204 of the spacer member 20 are engaged with each other. Consequently, the assembling foolproof function is achieved, and the production yield is increased.

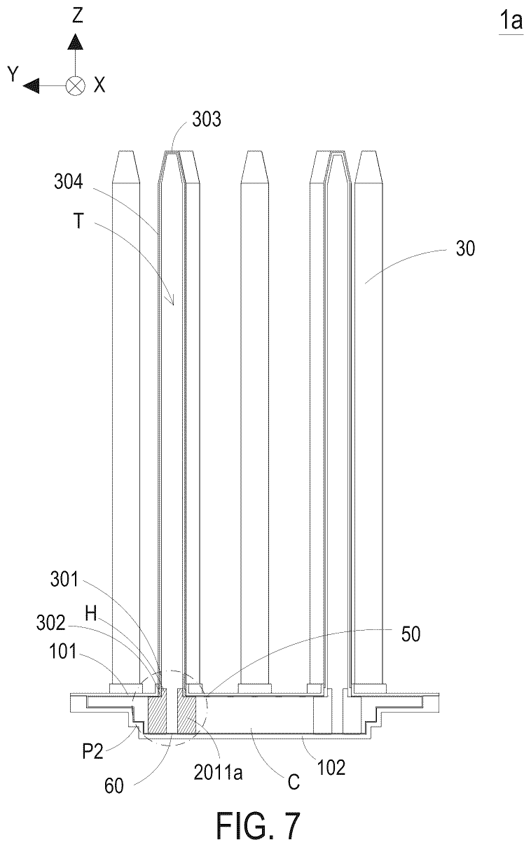

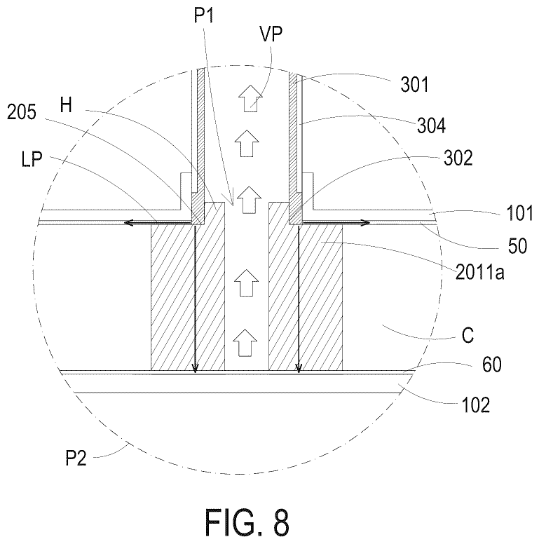

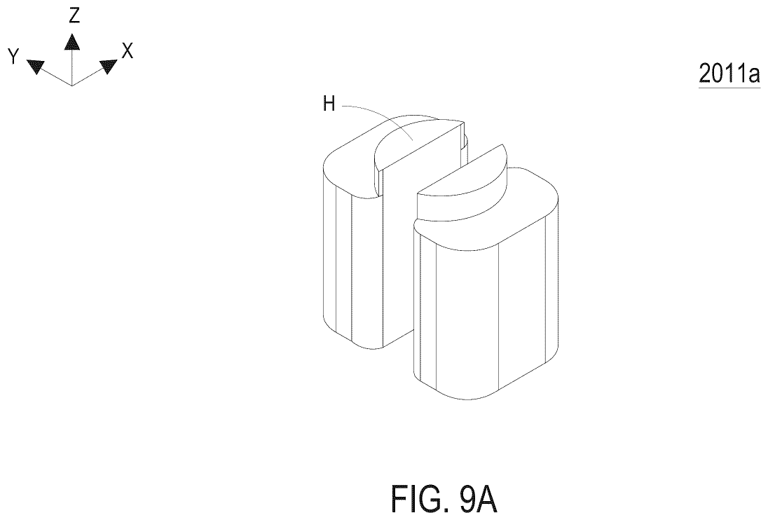

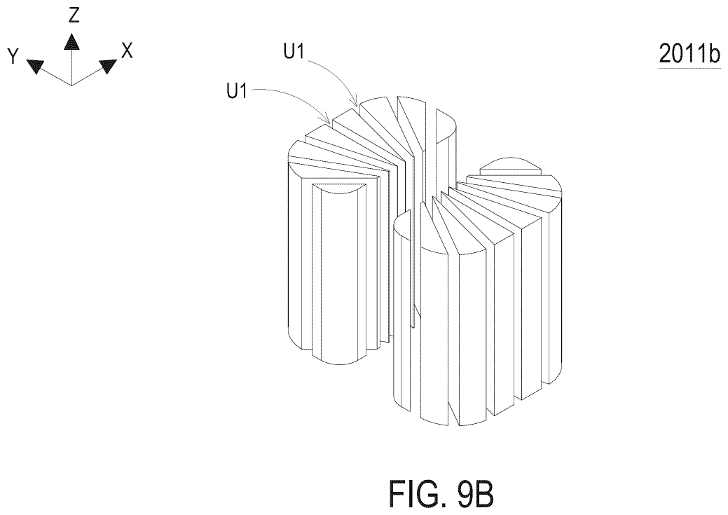

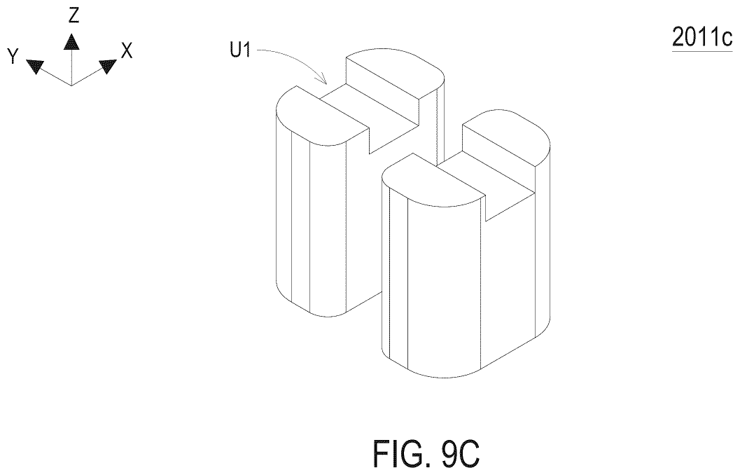

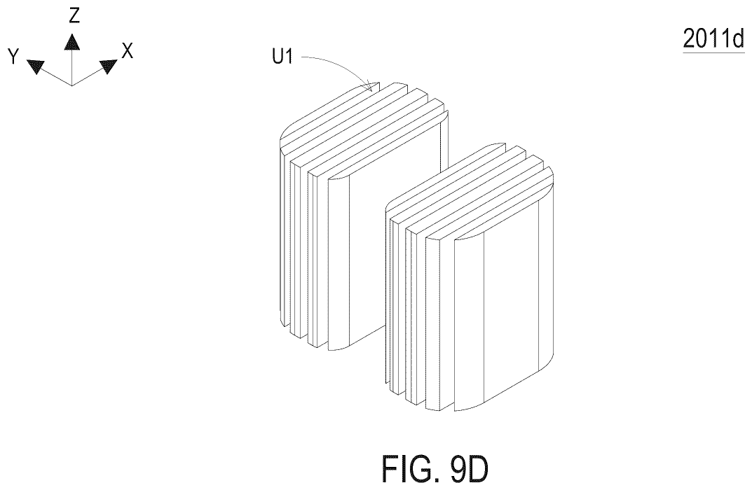

FIG. 7 is a schematic cross-sectional view illustrating a hollow pipe cooling device according to a second embodiment of the present invention. FIG. 8 is a schematic cross-sectional view illustrating an enlarged portion of the hollow pipe cooling device according to the second embodiment of the present invention. FIG. 9A is a schematic perspective view illustrating a first support structure of the hollow pipe cooling device according to the second embodiment of the present invention. Component parts and elements corresponding to those of the first embodiment are designated by identical numeral references, and detailed descriptions thereof are omitted. Similarly, the hollow pipe cooling device la includes a covering member 10, a spacer member 20 and at least one hollow pipe 30.

The covering member 10 includes a top cover 101 and a bottom cover 102. The top cover 101 and the bottom cover 102 are assembled with each other in a first direction z. In addition, an accommodation space C is formed between the top cover 101 and the bottom cover 102. The top cover 101 includes at least one top cover opening S1. The least one top cover opening S1 runs through the top cover 101. In addition, the at least one top cover opening S1 is in communication with the accommodation space C.

The spacer member 20 is disposed in the accommodation space C. In this embodiment, the spacer member 20 includes a plurality of support structures 201. In comparison with the first embodiment, the first support structures 2011a are distinguished. The first support structures 2011a are aligned with the corresponding top cover openings S1. Each of the first support structures 2011a is additionally equipped with a bulge H. The bulge H is extended in the first direction z. The plurality of hollow pipes 30 are aligned with the corresponding top cover openings S1.

Each hollow pipe 30 includes a surrounding wall part 304 and a closed end part 303. A first end of the surrounding wall part 304 is connected with the closed end part 303. A second end of the surrounding wall part 304 is an opened end part 302. A hollow pipe wick structure 301 is formed on an inner wall of the surrounding wall part 304. The top surface of the first support structure 2011a is contacted with the opened end part 302 of the corresponding hollow pipe 30. The bulge H is inserted into the corresponding hollow pipe 30. The bulge H is contacted with the hollow pipe wick structure 301. Due to the arrangement of the bulge H, the contact surface between the first support structure 2011a and the hollow pipe wick structure 301 is increased, and the heat dissipation efficiency is further enhanced.

FIG. 9B is a schematic perspective view illustrating a first support structure of a hollow pipe cooling device according to a third embodiment of the present invention. In this embodiment, the first support structure 2011b includes a plurality of grooves U1. The grooves U1 are in communication with the first flow channel P1. The grooves U1 are in a radial arrangement. Consequently, the efficiency of circulating the steam and the condensed liquid can be effectively enhanced.

FIG. 9C is a schematic perspective view illustrating a first support structure of a hollow pipe cooling device according to a fourth embodiment of the present invention. The first support structure 2011b includes a notch formed on an end portion thereof. FIG. 9D is a schematic perspective view illustrating a first support structure of a hollow pipe cooling device according to a fifth embodiment of the present invention. Similarly, the first support structure 2011d includes a plurality of grooves U1 formed on an end portion thereof and in parallel arrangement. Consequently, the cooling efficiency can be effectively enhanced.

It is noted that the type, the size, the arrangement and the number of the first support structures 2011, 2011a, 2011b, 2011c and 2011d can be varied according to practical requirements.

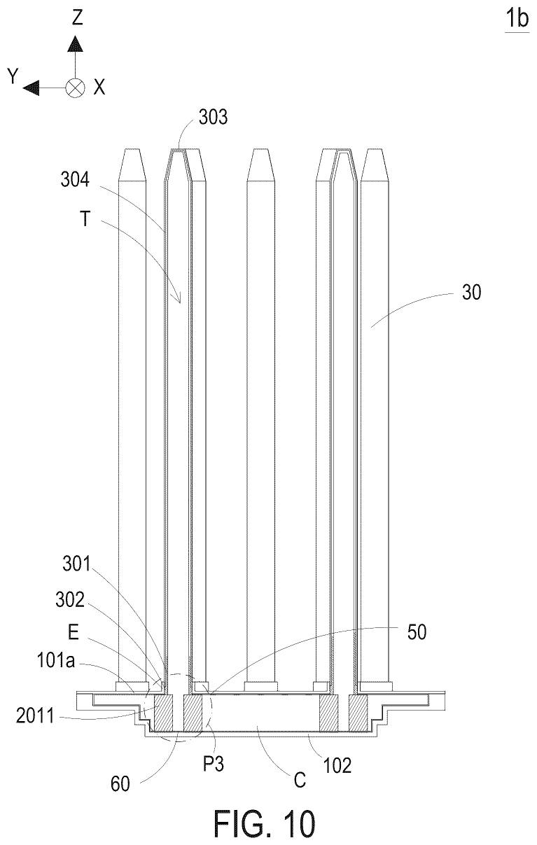

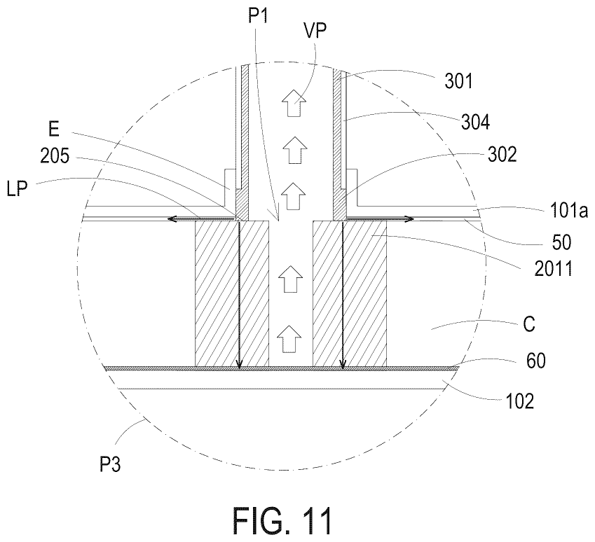

FIG. 10 is a schematic cross-sectional view illustrating a hollow pipe cooling device according to a sixth embodiment of the present invention. FIG. 11 is a schematic cross-sectional view illustrating an enlarged portion of the hollow pipe cooling device according to the sixth embodiment of the present invention. Component parts and elements corresponding to those of the first embodiment are designated by identical numeral references, and detailed descriptions thereof are omitted. Similarly, the hollow pipe cooling device 1b includes a covering member 10, a spacer member 20 and at least one hollow pipe 30.

The covering member 10 includes a top cover 101 and a bottom cover 102. The top cover 101 and the bottom cover 102 are assembled with each other in a first direction z. In addition, an accommodation space C is formed between the top cover 101 and the bottom cover 102. In this embodiment, the top cover 101 includes at least one top cover openings S1 and at least one extended portion E corresponding to the at least one top cover opening S1. The at least one top cover opening S1 runs through the top cover 101. In addition, the at least one top cover opening S1 is in communication with the accommodation space C.

The spacer member 20 is disposed in the accommodation space C. In this embodiment, the spacer member 20 includes at least one first support structure 2011. The at least one first support structure 2011 is aligned with the at least one top cover opening S1. A portion of the first support structure 2011 is aligned with and exposed to the top cover opening S1 in the first direction z.

The at least one hollow pipe 30 is aligned with the at least one top cover opening S1. Each hollow pipe 30 includes a surrounding wall part 304 and a closed end part 303. A first end of the surrounding wall part 304 is connected with the closed end part 303. A second end of the surrounding wall part 304 is an opened end part 302. A hollow pipe wick structure 301 is formed on an inner wall of the surrounding wall part 304. The top surface of the first support structure 2011 is contacted with the opened end part 302 of the corresponding hollow pipe 30. The at least one extended portion E of the top cover 101 encloses the surrounding wall part 304 of the corresponding hollow pipe 30. Due to the extended portion E of the top cover 101, the hollow pipe 30 is effectively guided to be penetrated through the corresponding top cover opening S1 until the hollow pipe 30 is contacted with the corresponding first support structure 2011. Since the surrounding wall part 304 of the hollow pipe 30 is pressure-tightened by the extended portion E of the top cover 101, the assembling structure will be firm, and the efficacy of avoiding the leakage of the steam vapor at this connection site will be increased.

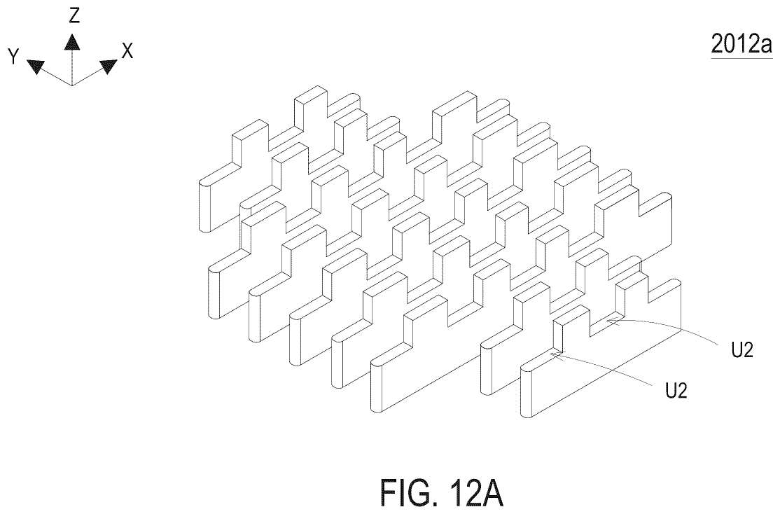

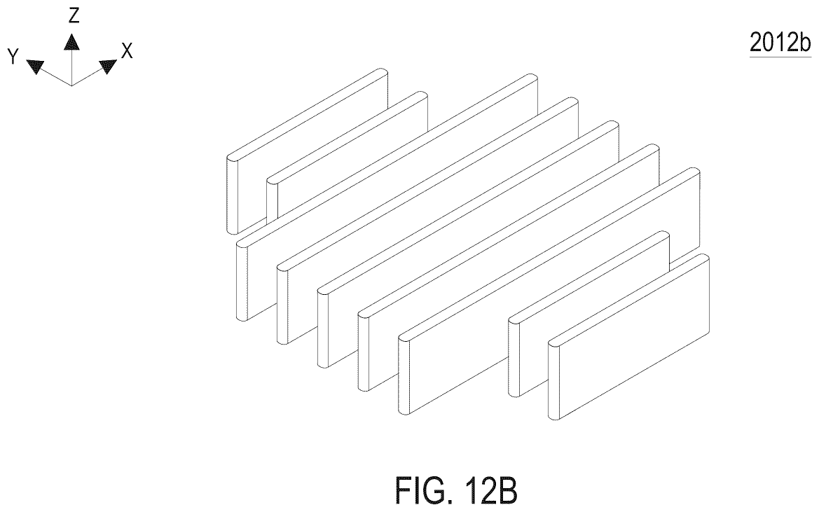

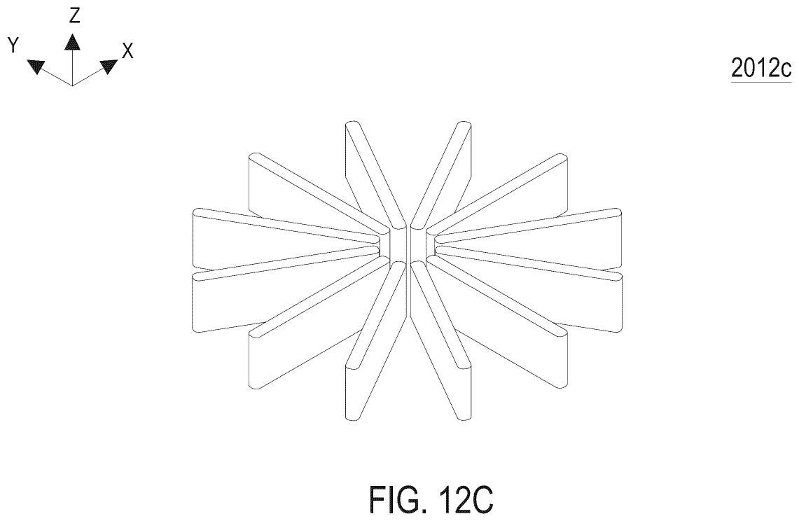

FIG. 12A is a schematic cross-sectional view illustrating a second support structure of a hollow pipe cooling device according to a seventh embodiment of the present invention. In this embodiment, the second support structures 2012a include parallel strips with notches U2. The notches U2 are in communication with the first flow channel P1. Consequently, the efficiency of circulating the steam and the condensed liquid can be effectively enhanced.

FIG. 12B is a schematic cross-sectional view illustrating a second support structure of a hollow pipe cooling device according to an eighth embodiment of the present invention. In this embodiment, the second support structures 2012b include parallel strips without notches.

FIG. 12C is a schematic cross-sectional view illustrating a second support structure of a hollow pipe cooling device according to a ninth embodiment of the present invention. In this embodiment, the second support structures 2012c include parallel strips extending outward from a center and in a radial arrangement.

It is noted that the type, the size, the arrangement and the number of the second support structures 2012, 2012a, 2012b, 2012c and 2012d can be varied according to practical requirements.

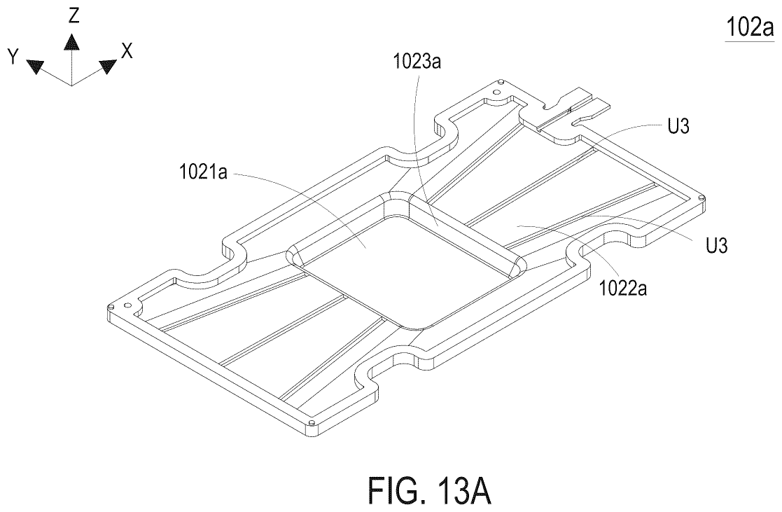

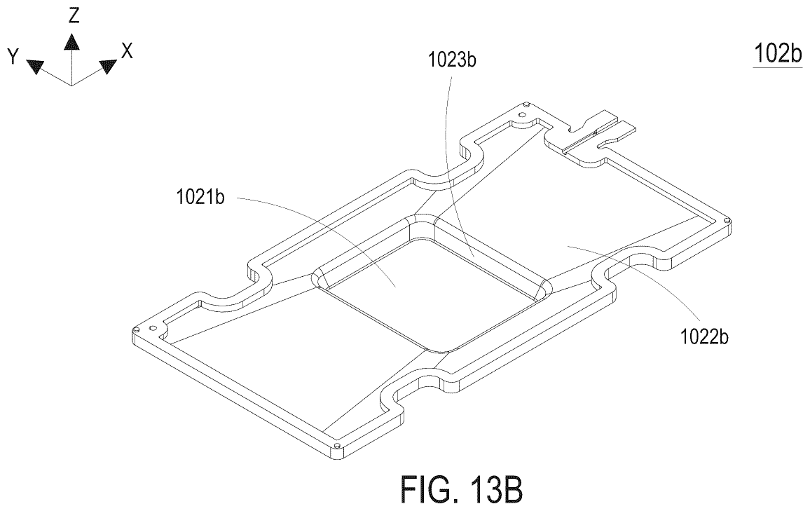

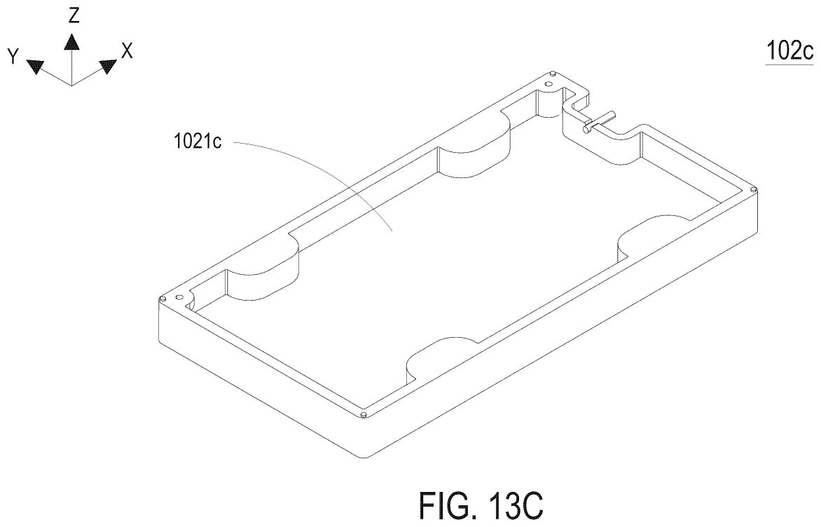

FIG. 13A is a schematic perspective view illustrating a bottom cover of the hollow pipe cooling device according to a tenth embodiment of the present invention. In this embodiment, the second area 1022a of the bottom cover 102 includes a plurality of trenches U3. The trenches U3 are in communication with the third flow channel P3. The three areas of the bottom cover 102 are related to each other to comply with the diversified design of the heat source appearance. Similarly, the altitude of the first area 1021a is lower than the altitude of the second area 1022a and the altitude of the third area 1023a in the first direction z. The first area 1021a of the bottom cover 102 is in contact with a heat source (not shown). The condensed liquid is collected in the first area 1021a of the bottom cover 102 through the second area 1022a and the third area 1023a of the bottom cover 102. In this embodiment, the second area 1022a has a slant surface with the trenches U3. The second area 1022a is connected with the third area 1023a. The side of the second area 1022a close to the third area 1023a is at the level lower than the side of the second area 1022a away from the third area 1023a. The condensed liquid collected in the first area 1021 of the bottom cover 102 is sublimated into steam by the heat source. Consequently, the circulating and cooling function can be achieved.

FIG. 13B is a schematic perspective view illustrating a bottom cover of the hollow pipe cooling device according to an eleventh embodiment of the present invention. In this embodiment, the second area 1022b of the bottom cover 102 has a slant surface without trenches. Consequently, the condensed liquid is guided to the region corresponding to the heat source.

FIG. 13C is a schematic perspective view illustrating a bottom cover of the hollow pipe cooling device according to a twelfth embodiment of the present invention. In this embodiment, the first area 1021c of the bottom cover 102 is flat. The structural design is suitable for the large-size heat source. The condensed liquid can be spread over the whole first area 1021c of the bottom cover 102 to increase the cooling efficacy.

It is noted that the type and design of the bottom covers 102, 102a, 102b or 102c are not restricted. That is, the type and design of the bottom cover may be varied according to the practical requirements.

From the above descriptions, the present invention provides the hollow pipe cooling device. The exposed portion of the support structure in the covering member and the opened end pat of the hollow pipe are aligned with each other. In addition, the support structure is contacted with the opened end pat of the hollow pipe. Consequently, the cooling performance is enhanced, and the overall structural strength is increased. Since the hollow pipe can be well supported by the corresponding first support structure, the opened end pat of the hollow pipe has better structural rigidity. Since the surrounding wall part of the hollow pipe is pressure-tightened by the extended portion of the top cover, the hollow pipe can well withstand the internal steam pressure. The first support structure opening of the first support structure opening in the covering member is aligned with the corresponding hollow pipe, so that a communication flow channel is defined. Consequently, the efficiency of circulating the steam and the condensed liquid is enhanced. Furthermore, the wick structures are contacted with each other through various components, and thus the capillary action is smoothly performed. Since the condensed liquid is guided and returned to the region corresponding to the heat source, the cooling efficiency is enhanced. Furthermore, the bulge of the first support structure is inserted into the opened end part of the hollow pipe. Since the contact area between the first support structure and the hollow pipe wick structure is increased, the cooling performance is enhanced. Furthermore, since the first flow channel, the second flow channel and the third flow channel are in communication with each other and the shape, position and material of the support structure are diversified, the cooling efficiency is enhanced. The bottom cover is divided into a plurality of areas. These areas are connected with each other. The bottom cover can be used to support the support structure. Furthermore, the altitudes of different areas of the bottom cover are changed according to the practical requirements. Consequently, the condensed liquid can be returned to the region corresponding to the heat source at a faster speed, and the cooling efficiency will be increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A hollow pipe cooling device, comprising:
a covering member comprising a top cover and a bottom cover, wherein the top cover and the bottom cover are combined together to form an accommodation space therebetween, wherein the top cover comprises at least one top cover opening, and the least one top cover opening runs through the top cover in a first direction and is in communication with the accommodation space;
a spacer member disposed in the accommodation space, wherein the spacer member has a top surface, and the top surface is partially exposed to the at least one top cover opening; and
at least one hollow pipe, wherein each of the at least one hollow pipe comprises a surrounding wall part and a closed end part, wherein a first end of the surrounding wall part is connected with the closed end part, a second end of the surrounding wall part is an opened end part, a heat dissipation space is defined by the surrounding wall part and the closed end part collaboratively, and the opened end part is used as an entrance/exit of the heat dissipation space,
wherein a hollow pipe wick structure is formed on an inner wall of the surrounding wall part, and the opened end part is aligned with the corresponding top cover opening and contacted with the spacer member.

2. The hollow pipe cooling device according to claim 1, wherein the hollow pipe cooling device further comprises a top wick structure, and the top wick structure is disposed on a surface of the top cover facing the accommodation space.

3. The hollow pipe cooling device according to claim 2, wherein the spacer member is contacted with the top wick structure.

4. The hollow pipe cooling device according to claim 2, wherein the top wick structure is a grooved structure, a copper powder sintered structure, a woven mesh structure or a composite structure.

5. The hollow pipe cooling device according to claim 1, wherein the hollow pipe cooling device further comprises a bottom wick structure disposed on a surface of the bottom cover facing the accommodation space.

6. The hollow pipe cooling device according to claim 5, wherein the spacer member is contacted with the bottom wick structure.

7. The hollow pipe cooling device according to claim 5, wherein the bottom wick structure is a grooved structure, a copper powder sintered structure, a woven mesh structure or a composite structure.

8. The hollow pipe cooling device according to claim 1, wherein the bottom cover comprises a first area, a second area and a third area, wherein the second area is arranged around the first area, the second area and the first area are located at different horizontal planes, the third area is connected with the second area and the first area, and the third area is arranged between the second area and the first area.

9. The hollow pipe cooling device according to claim 1, wherein the spacer member is a convex structure, a battlement structure, a sawtooth structure or a columnar structure.

10. The hollow pipe cooling device according to claim 1, wherein the spacer member is a copper powder sintered structure, a woven mesh structure or a composite structure.

11. The hollow pipe cooling device according to claim 1, wherein the spacer member comprises a plurality of support structures, and the plurality of support structures are in a parallel arrangement, a mesh arrangement or a radial arrangement.

12. A hollow pipe cooling device, comprising:
a covering member comprising a top cover and a bottom cover, wherein the top cover and the bottom cover are combined together to from an accommodation space therebetween, wherein the top cover comprises at least one top cover opening, and the least one top cover opening runs through the top cover in a first direction and is in communication with the accommodation space;
a spacer member disposed in the accommodation space, and comprising a top surface and at least one bulge, wherein the top surface is partially exposed to the at least one top cover opening, and the at least one bulge is extended in the first direction; and
at least one hollow pipe, wherein each of the at least one hollow pipe comprises a surrounding wall part and a closed end part, wherein a first end of the surrounding wall part is connected with the closed end part, a second end of the surrounding wall part is an opened end part, a heat dissipation space is defined by the surrounding wall part and the closed end part collaboratively, and the opened end part is used as an entrance/exit of the heat dissipation space,
wherein a hollow pipe wick structure is formed on an inner wall of the surrounding wall part, and the opened end part is combined with the corresponding top cover opening.

13. The hollow pipe cooling device according to claim 12, wherein the hollow pipe cooling device further comprises a top wick structure, and the top wick structure is disposed on a surface of the top cover facing the accommodation space.

14. The hollow pipe cooling device according to claim 13, wherein the spacer member is contacted with the top wick structure.

15. The hollow pipe cooling device according to claim 12, wherein the hollow pipe cooling device further comprises a bottom wick structure, and the bottom wick structure is disposed on a surface of the bottom cover facing the accommodation space.

16. The hollow pipe cooling device according to claim 15, wherein the spacer member is contacted with the bottom wick structure.

17. The hollow pipe cooling device according to claim 12, wherein the bottom cover comprises a first area, a second area and a third area, wherein the second area is arranged around the first area, the second area and the first area are located at different horizontal planes, the third area is connected with the second area and the first area, and the third area is arranged between the second area and the first area.

18. The hollow pipe cooling device according to claim 12, wherein the spacer member is a convex structure, a battlement structure, a sawtooth structure or a columnar structure.

19. The hollow pipe cooling device according to claim 12, wherein the spacer member comprises a plurality of support structures, and the plurality of support structures are in a parallel arrangement, a mesh arrangement or a radial arrangement.

20. A hollow pipe cooling device, comprising:
a covering member comprising a top cover and a bottom cover, wherein the top cover and the bottom cover are combined together to from an accommodation space therebetween, wherein the top cover comprises at least one top cover opening and at least one extended portion, the least one top cover opening runs through the top cover in a first direction and is in communication with the accommodation space, and the at least one extended portion is externally extended from the corresponding top cover opening;
a spacer member disposed in the accommodation space, wherein the spacer member has a top surface, and the top surface is partially exposed to the at least one top cover opening; and
at least one hollow pipe, wherein each of the at least one hollow pipe comprises a surrounding wall part and a closed end part, wherein a first end of the surrounding wall part is connected with the closed end part, a second end of the surrounding wall part is an opened end part, a heat dissipation space is defined by the surrounding wall part and the closed end part collaboratively, and the opened end part is used as an entrance/exit of the heat dissipation space,
wherein a hollow pipe wick structure is formed on an inner wall of the surrounding wall part, the opened end part is aligned with the corresponding top cover opening and contacted with the spacer member, and the opened end part is enclosed by the corresponding extended portion of the top cover.
